(19) United States
(12) Patent Application Publication
(10) Pub. No.: US 2026/0324414 A1
(43) Pub. Date: Oct. 15, 2026

(54) ASYMMETRICAL DIGITAL CELLS EMBEDDED WITH BEOL CAPACITORS

(71) Applicant: Taiwan Semiconductor Manufacturing Company, Ltd., Hsinchu (TW)

(72) Inventors: Yi-Che Chen, New Taipei City 242 (TW); Chia-Chung Chen, Hsinchu (TW); Chung-Sheng Yuan, Taipei City (TW); Yi-Kan Cheng, Taipei City (TW)

(73) Assignee: Taiwan Semiconductor Manufacturing Company, Ltd., Hsinchu (TW)

(21) Appl. No.: 19/177,341

(22) Filed: Apr. 11, 2025

(51) Int. Cl. H01L 23/522; H01L 23/528; H10D 84/85

(52) U.S. Cl. CPC H10W 20/496; H10D 84/85; H10W 20/43

(57) ABSTRACT

Asymmetrical digital cells embedded with capacitors are provided. In one aspect of the present disclosure, a semiconductor device includes a first spatial region for digital design cells. The first spatial region includes a metal-oxide-metal (MOM) capacitor. The mom capacitor includes a first plurality of lines of a first electrode of the MOM capacitor interleaved with a second plurality of lines of a second electrode of the MOM capacitor at a first metallization layer. The semiconductor device includes a second spatial region (e.g., laterally spaced from the first spatial region).

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon. Interconnections between the devices can be formed from interconnects formed in metallization layers, according to various middle or back end-of line (MEOL, BEOL) processes. As the semiconductor industry has progressed into nanometer technology process nodes in pursuit of higher device density, improved performance, and lower costs, challenges from both fabrication and design issues have resulted in the development one or more sets of design rule checks (DRC) per node. Moreover, various components (e.g., passive components such as capacitors) may be implemented according to MEOL or BEOL processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top view of a semiconductor device, in accordance with some embodiments.

FIG. 2 illustrates an example flow chart of a method for fabricating a semiconductor device, in accordance with some embodiments.

FIG. 3 illustrates a top view of transistors formed over an active surface of a substrate according to the method of FIG. 2, in accordance with some embodiments.

FIGS. 4, 5, 6, 7, and 8 illustrate example top views of various metallization layers of a capacitor of a semiconductor device according to the method of FIG. 2, in accordance with some embodiments.

FIG. 9 illustrates an unstacked layer diagram for layers of the capacitor of FIGS. 4-8, in accordance with some embodiments.

FIG. 10 illustrates a capacitance extraction diagram, in accordance with some embodiments.

FIG. 11 illustrates an example method of circuit operation, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Semiconductor devices can include various regions according to functional, dimensional, electro-magnetic inter-operability, and other organizational criterion. For example, co-locating various analog circuits into an analog region can localize shielding, or reduce mutual interferences, relative to the rapid transitions of a digital logic domain. Accordingly, a first region (e.g., lateral spatial region over an active surface of a semiconductor device) can be designated as an analog domain. Analog circuits, organized into analog design cells, may be designated, fabricated, or disposed in such a region. A second region (e.g., a lateral spatial region laterally spaced from the first region) can be designated as a digital domain. Digital circuits, organized into digital design cells, may be designated, fabricated, or disposed in such a region. DRC, including DRC for metallization layers can be harmonized or distinct for the analog and digital regions. The formation of capacitors may be substantially influenced by these DRC, since the DRC may restrict geometry of lines or via structures formed in the metallization layers, and because the geometry of these capacitors largely defines their capacitance (for a given metallization material and interlayer dielectric, ILD).

Generally, capacitors formed from metallization layers can be provided in an analog domain. Such capacitors can provide shielding, as may reduce the mutual interference between various circuits of the wireless domain. However, placement of these capacitors in a digital domain can impact circuit operation. For example, the capacitance can delay signal propagation, as may result in undesired race condition resolutions, place excess load capacitance on high-speed interconnects, and provide capacitive coupling signal paths as may interfere with further clocks, strobes, or other signals or circuits of the semiconductor device. Moreover, DRC for a digital logic region can prohibit some capacitor geometries, as may otherwise be used. For example, defined track widths configured for high-speed logic or power delivery can conflict with certain capacitor geometries (e.g., regular interleaved grids).

Such examples should not be construed as limiting. For example, some analog circuits can prove susceptible to, for example, signal delay associated with stray capacitance. Conversely, some digital circuits can exhibit substantial closure margin, such that the stray capacitance has little effect of circuit operation. Accordingly, aspects of the present disclosure may be used with each of an analog domain or a digital domain.

In some embodiments, any effect of the capacitance can affect transistors asymmetrically. For example, a bias voltage applied via a ripple current in the capacitor, or a capacitive coupling of a source to drain current can impact n-type and p-type capacitors differently. For example, a signal across the capacitor electrodes can cause an imbalance between a threshold voltage, such that leakage across p-type transistors exceeds that of n-type transistors, given similar gate geometries (e.g., contact areas between a gate oxide/electrode and a channel). Such examples should not be construed as limiting. For example, a greater electron mobility of an n-type channel can exceed other effects such that leakage across n-type transistors may exceed that of p-type transistors given similar gate geometries, in some embodiments. Asymmetric gate contact areas can be configured to normalize a leakage across an n-channel of an n-type transistor and a p-channel of the p-type transistor. This current can refer to an induced current of a time-varying signal applied to the capacitor, or a component of a signal impacted by stray capacitance (e.g., a capacitive loading skewing the propagation of a digital signal). Moreover, differences in materials, doping levels, or other aspects can impact a balanced operation of a leakage current, voltage threshold, capacitive coupling, or other aspects of p- or n-type transistors, or other circuity as may be disposed on an active surface of the semiconductor device.

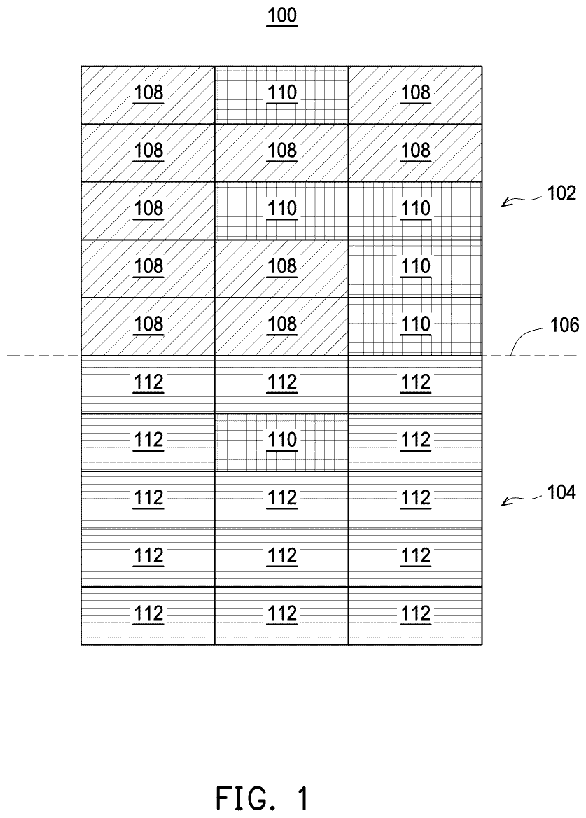

Referring now to FIG. 1, a top view of a semiconductor device 100 is provided in accordance with some embodiments of the present disclosure. The semiconductor device 100 includes various regions including a first region 102, as is designated or designed as a digital logic domain. A second region 104 is designated or designed as another domain, and more particularly, as an analog logic domain. Further adjacent or non-adjacent regions can include further analog or digital domains, as may or may not be compatible to abut the first region 102 and the second region 104. Further still, additional adjacent or non-adjacent regions can include further region types, such as mixed-signal domains, radio frequency (RF) domains, clock and timing domains, I/O domains, and so forth.

A boundary 106 separates the first region 102 from the second region 104. As depicted, the boundary 106 can include or consist of a logical demarcation between separate regions. In some embodiments, the boundary 106 can further include shielding, guard rings, spacings for routing, or other physical features.

Referring to the first region 102 in greater detail, the first region 102 includes various (digital) design cells including various components. For example, active circuity digital design cells 108 can include transistors, diodes, or other active circuit components. The active circuity of the active circuity digital design cells 108 can include interconnects formed thereover via various of the metallization layers. Capacitive design cells 110 can include at least one capacitor, such as a metal-oxide-metal capacitor. For example, the metal-oxide-metal capacitor can include lines of the metallization layers as electrodes of the capacitors, with an interlayer dielectric (ILD) as the dielectric of the capacitor. Capacitive design cells 110 can be coupled with adjoining or other digital design cells 108 of the digital logic domain, or may be coupled with other portions of the semiconductor device 100 (e.g., as bulk capacitance for a power rail). The combination of the capacitive design cells 110 with other digital design cells 108 can form memory devices, flip flops, latches, registers, counters, and so forth.

Referring to the second region 104 in greater detail, the second region 104 includes various analog design cells including various components. For example, active circuity analog design cells 112 can include transistors, diodes, or other active circuit components. The active circuity of the analog design cells 112 can include interconnects formed thereover via various of the metallization layers. The combination of the analog design cells 112 can form operational amplifiers, signal references, filters, integrators, comparators, and so forth. As for the first region 102, the second region 104 can include capacitors. For example, analog capacitive design cells 110 can include at least one capacitor, such as a metal-oxide-metal (MOM) capacitor.

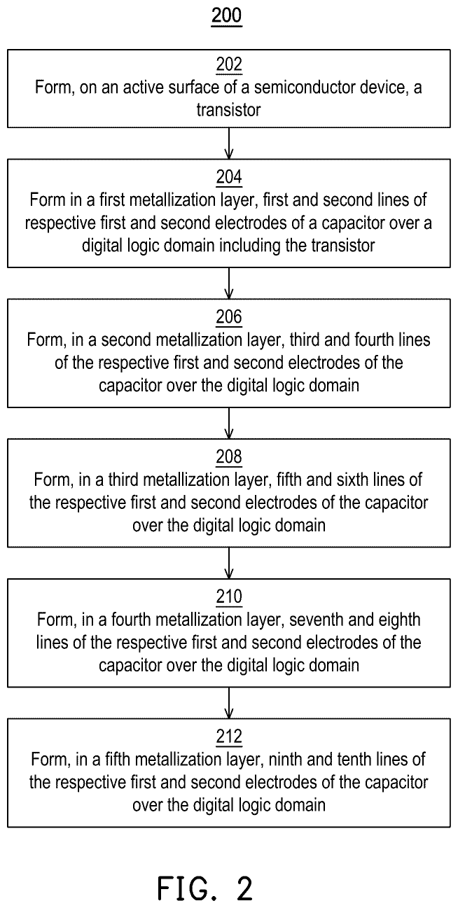

FIG. 2 illustrates an example flow chart of a method 200 for fabricating a semiconductor device, in accordance with some embodiments of the present disclosure. For example, at least some of the operations (or steps) of the method 200 can be used to form a semiconductor device such as, for example, a semiconductor device having a MOM capacitor in a digital design domain. Further, the method 200 can be used to form a semiconductor device 100 including a MOM capacitor in other domains, such as an analog domain. The term “n-type,” as used herein, may be referred to as the conduction type of a transistor having electrons as its principal conduction carrier; the term “p-type,” as used herein, may be referred to as the conduction type of a transistor having holes as its principal conduction carrier.

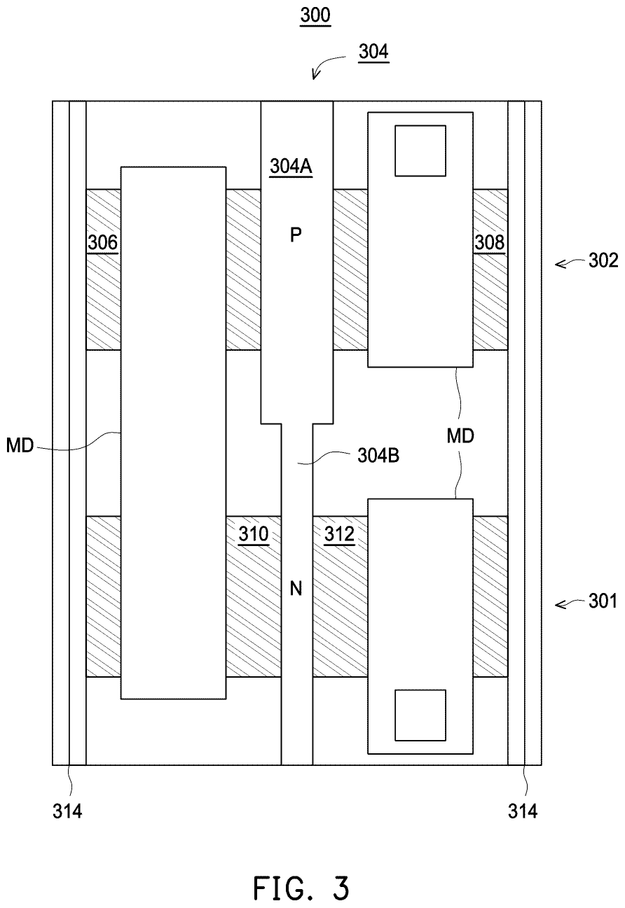

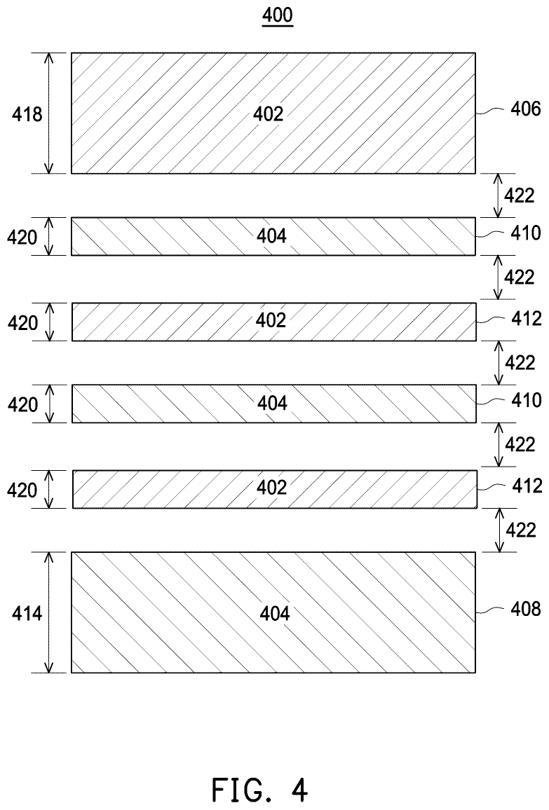

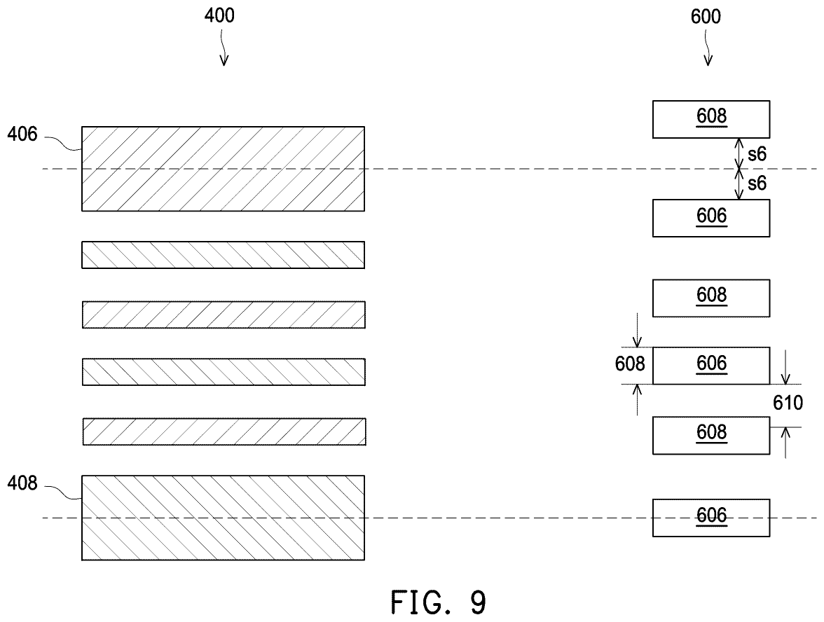

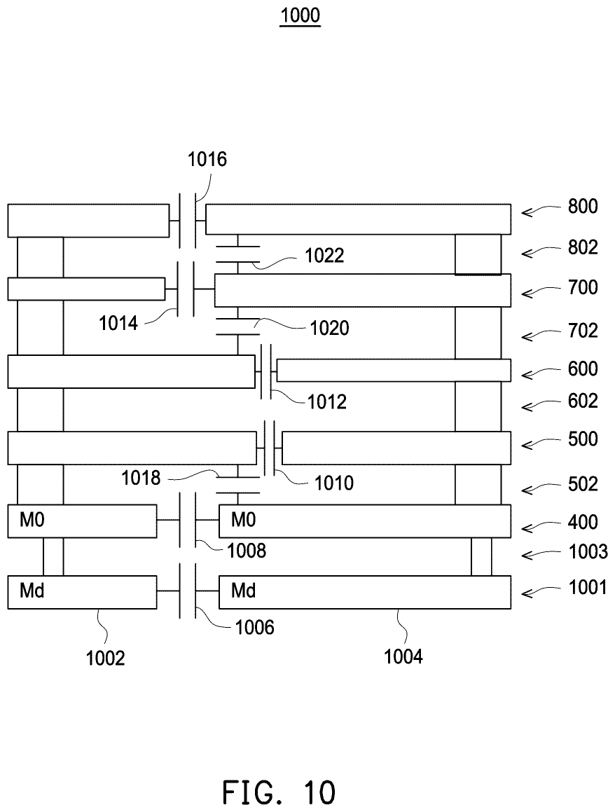

It is noted that the method 200 is merely an example, and is not intended to limit the present disclosure. Accordingly, it is understood that additional operations may be provided before, during, and after the method 200 of FIG. 2, and that some other operations may only be briefly described herein. For example, further lines can be formed vertically over the transistors to couple with one or more electrodes of the capacitor, or to couple with further logic cells. In various embodiments, operations of the method 200 may be associated with perspective views of a semiconductor device including a capacitor at various fabrication stages as shown in FIGS. 3, 4, 5, 6, 7, and 8, respectively. For purposes of clarity of illustration, FIGS. 9 and 10 provide an unstacked layer diagram and a capacitance extraction diagram, respectively, for layers of the capacitor formed in metallization layers as depicted in FIGS. 4-8.

In brief overview, the method 200 starts with operation 202 of forming, on an active surface of a semiconductor device, a transistor. Next, the method 200 proceeds to operation 204 of forming first and second lines of a capacitor in a first metallization layer. Next, the method proceeds to operation 206 of forming third and fourth lines of the capacitor in a second metallization layer. Next, the method proceeds to operation 208 of forming fifth and sixth lines of the capacitor in a third metallization layer. Next, the method proceeds to operation 210 of forming seventh and eighth lines of the capacitor in a fourth metallization layer. Next, the method proceeds to operation 212 of forming ninth and tenth lines of the capacitor in a fifth metallization layer.

As mentioned above, FIGS. 3-8 each illustrate, in a top view, a portion of the semiconductor device 100, at various fabrication stages of the method 200 of FIG. 2. For example, FIG. 3 illustrates a formation of a p-type and n-type capacitor; FIGS. 4-8 illustrate a top view of a capacitor of the same region (e.g., digital design domain) of the semiconductor device 100. Although FIGS. 3-8 illustrate the semiconductor device 100, it is understood that the semiconductor device 100 may include a number of other devices such as inductors, fuses, capacitors, coils, etc., which are not shown for purposes of clarity of illustration.

Corresponding to operation 202 of FIG. 2, FIG. 3 illustrates a top view of transistors formed over an active surface of a substrate. More particularly, a complementary field effect transistor (CFET) pair 300 of an n-type transistor 301 and a p-type transistor 302 are depicted. The active area of a same or other design cell (e.g., digital logic design cell 108) can include further transistors, diodes, or other components to implement various digital logic functionality. The depicted CFET pair 300 is depicted to illustrate an asymmetric gate structure 304 between the n-type transistor 301 and the p-type transistor 302. The asymmetric gate structures provide a varying gate contact area between the transistors of different types. Such an asymmetrical implementation can compensate for imbalances between n-type components (e.g., transistor 301) and p-type components (e.g., transistors 302). The asymmetrical implementation may be provided for other transistors, even where the same gate is not coupled with both transistors 301, 302.

The transistors can include a planar, FinFET, or other transistor types according to various implementations of the present disclosure. Accordingly, although depicted as varying a lateral width of the gate over a planar (or finned) channel, the present disclosure further contemplates other gate asymmetries as may be implemented for other transistor geometries. For example, for a gate all around (GAA) transistor geometries, an axial dimension of the gate may be extended, a gate oxide thickness can be increased or decreased, or so forth.

The n-type transistor 301 and the p-type transistor 302 can be disposed in a digital logic domain (e.g., in a same or abutting digital logic cells 108). Such a digital logic cell 108 can further abut another design cell including a design cell 110 including the capacitor referred to herein (e.g., a MOM capacitor).

Corresponding to operation 204 of FIG. 2, FIG. 4 illustrates a top view of a first metallization layer 400 formed over an active surface of a substrate of the semiconductor device 100. The depicted portion of the first metallization layer 400 may be laterally spaced from the transistors 301, 302 of FIG. 3. For example, the depicted first metallization layer 400 can be provided in an abutting or other design cell of a same digital domain as the transistors 301, 302 or otherwise provided proximally so as to couple with the transistors 301, 302 (e.g., across a boundary 106). In some embodiments, the transistors 301, 302 and the MOM can be formed in a same design cell. A capacitor can extend across multiple design cells (e.g., according to a continuous line extending across the design cells). In some embodiments, multiple instances of the depicted design cell can be provided physically abutting one another. In some embodiments, multiple contiguous or non-contiguous capacitors can electrically connect with one another (e.g., in a parallel configuration). The various first lines can be connected to one another by an MD structure (e.g., a titanium contact plug extending over the active surface), or by further interconnect lines electrically coupling the depicted first lines 402 and second lines 404.

The first metallization layer 400 may correspond to a lowermost metallization layer (sometimes referred to as an M0 or M1 layer), or as another layer, such as an uppermost or medial layer. Accordingly, the operations of the present method 200 may be performed in various sequences. For example, the operations may be performed according to the provided sequence to form a first capacitor structure, or reverse from the provided sequence to form a second capacitor structure inversed, relative to the first capacitive structure.

The depicted lines of the first metallization layer 400 include first lines 402 of a first electrode of the capacitor (e.g., a first supply voltage, such as VDD). The depicted lines of the first metallization layer 400 include second lines 404 of a second electrode of the capacitor (e.g., a second supply voltage, such as a reference voltage, VSS). The first lines 402 are interleaved with the second lines 404, such that a cross sectional area for the capacitor (according to the two-dimensional view) includes the majority of the outer edges of the depicted first lines 402 and second lines 404. More particularly, other than one line disposed at a first lateral extreme (depicted as top) and another line disposed at a second lateral extreme, opposite from the first lateral extreme (depicted as bottom), the two longest edges of each of the lines forms a portion of a surface area in the depicted two-dimensional plane. Moreover, the outermost lines (e.g., sometimes referred to as tracks 406, 408 without limiting effect) can include different dimensions than other of the lines. For example, outermost lines for all or any of the metallization layers can have a width which is greater than or equal to other lines of a same metallization layer. Such an implementation may accord to routing DRC for the digital logic region. In some cases, these DRC may include a voltage level intended to avoid cross-talk between digital logic cells. For example, lines for the first supply voltage, VCC and the second supply voltage, VSS, may be form tracks 406, 408 shared with other digital logic cells of the region.

These tracks 406, 408 can include a defined width, as may vary from other lines disposed therebetween. For example, one of the first lines (e.g., a first track 406) can be provided with a width 418 of about 18 nanometers (e.g., between about 16 nm and about 20 nm). Other of the first lines 402 can be provided with a width 420 of about 11 nm (e.g., between about 9 nm and about 13 nm). Similarly, one of the second lines 404 (e.g., a second track 408) can be provided with a width 414 of about 19 nanometers (e.g., between about 17 nm and about 21 nm). Providing a somewhat lower resistance path for ground can configure the path to receive somewhat larger currents, or better maintain a ground place, relative to a power plane of another supply voltage.

Other of the second lines 404 can be provided with a width 420 of about 11 nm (e.g., between about 9 nm and about 13 nm). For example, a width 420 of the other of the first lines 402 can (but need not) be equal to a width 420 of the other of the second lines 404. These lines 410, 412 can correspond to interconnect spacings available for a digital design domain (e.g., a fixed or smallest spacing and width to provide higher capacitance than other approaches). Spacings between any of the lines 406, 408, 410, 412 may be provided as equal. For example, at least the other (non-top/bottom) first and second lines 410, 412 of the first metallization layer 400 can be provided with a same spacing of about 9.5 nm (e.g., between about 8 nm and 11 nm). In some embodiments, all spacings 422 of the first metallization layer 400 (at least for the capacitor), are provided as the same value (e.g., about 9.5 nm or otherwise between about 8 nm and about 11 nm as indicated above).

The depicted spacings 422, as well as further lateral spacings of other layers and vertical spacings between layers can include at least one ILD material. In some embodiments, this ILD is provided uniformly across various portions of the semiconductor device 100. For example, silicon dioxide (SiO2) can form an oxide of the capacitor, or can be substituted for another dielectric, such as Silicon Carbon Nitride (SiCN), as may be further integrated with other ILD portions of the semiconductor device 100. In some embodiments, a high-k dielectric is used for the capacitor portion, which is different from an ILD for other portions of the device. Such an implementation can increase capacitance, but may add process steps and complexity, such as increasing a number of patterning steps, or involving depositing of anti-diffusion barrier layers, etch stop layers, and the like. Accordingly, a silicon dioxide or other ILD suitable for various portions of the device can be used to avoid this additional complexity, where a provided capacitance is suitable for a given function.

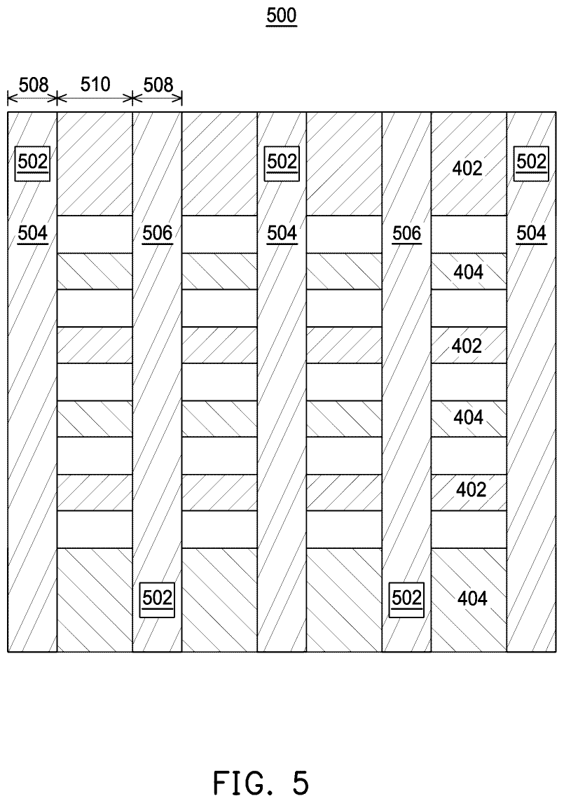

Corresponding to operation 206 of FIG. 2, FIG. 5 illustrates a top view of a second metallization layer 500 over an active surface of a substrate. More particularly, the second metallization layer 500 is depicted as formed over the first metallization layer 400, such as where the first and second metallization layers 400, 500 correspond to an M0 and M1 layer, though such a configuration should not be construed as limiting (as described above). The lines of the second metallization layer 500 extend in a second lateral direction, perpendicular to a first lateral direction of lines of the first metallization layer 400. The lines electrically couple with the first lines 402 and second lines 404 of the capacitor by via structures, depicted upon the foreground for clarity, but which are disposed between the first metallization layer 400 and the second metallization layer, as is depicted in FIG. 10, hereinafter.

The lines of the second metallization layer 500 include third lines 504 coupled with the first supply voltage and fourth lines 506 coupled with the second supply voltage. Accordingly, the third lines 504 may be referred to as a portion of the first electrode and the fourth lines may be referred to as a portion of the second electrode. The third lines 504 and fourth lines 506 can be provided with varying, or, as depicted, equal widths and spacings. For example, the third and fourth lines 504, 506 may be provided as having a width 508 of about 24 nm and a spacing 510 of at least about 20 nm.

The various via structures (e.g., the depicted via structures 502 of FIG. 5) can be formed according to a single or double damascene process, along with the lines. For example, a surface of the semiconductor can be patterned to form openings to deposit at least one of the via structures or lines. Such a process can include a Plasma-Enhanced Chemical Vapor Deposition (PECVD) Chemical Vapor Deposition (CVD) or other process, along with a chemical mechanical polishing or grinding process (CMP/G) or other planarization process. Such operations can be alternatively repeated to form the various metallization layers provided herein, or can be substituted for further appropriate operations. The via structures 502 are depicted as landed on the tracks 406, 408 of the first metallization layer 400, as may aid with alignment and formation of a low resistance electrical connection therebetween. However, via structures may be landed on other portions of the metallization layers (e.g., other lines) some examples of which are depicted throughout the provided figures.

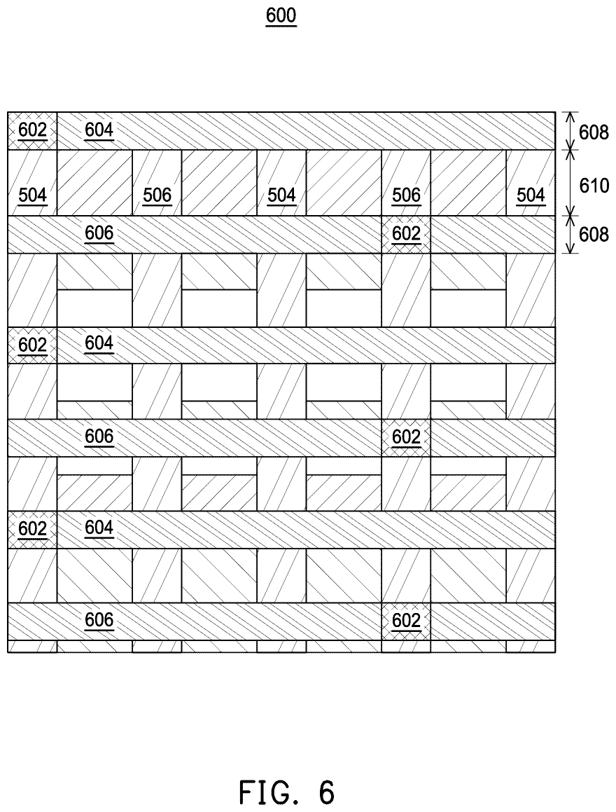

Corresponding to operation 208 of FIG. 2, FIG. 6 illustrates a top view of a third metallization layer 600 formed over an active surface of a substrate. More particularly, the third metallization layer 600 is depicted as formed over the second metallization layer 500, such as where the first, second, and third metallization layers 400, 500, 600 correspond to M0, M1, and M2 layers. The lines of the third metallization layer 600 extend in the lateral direction parallel to the first lateral direction of lines of the first metallization layer 400, and perpendicular to the second lateral direction of lines of the second metallization layer 500. The lines electrically couple with the third lines 504 and fourth lines 506 of the capacitor by via structures 602, depicted upon the foreground for clarity, but which are disposed between the second metallization layer 500 and the third metallization layer 600.

The lines of the third metallization layer 600 include fifth lines 604 coupled with the first supply voltage and sixth lines 606 coupled with the second supply voltage. Accordingly, the fifth lines 604 may be referred to as a portion of the first electrode and the sixth lines 606 may be referred to as a portion of the second electrode. The fifth lines 604 and sixth lines 606 can be provided with varying, or, as depicted, equal widths and spacings. For example, the fifth and sixth lines 604, 606 may be provided as having a width 608 of about 12 nm and a spacing 610 of about 12.5 nm. A quantity of the total lines of the third metallization layer 600 can exceed a quantity of the total lines of the second metallization layer 500. That is, a sum of a quantity of the fifth lines 604 and the sixth lines 606 can exceed a sum of a quantity of the fifth lines 604 and the sixth lines 606.

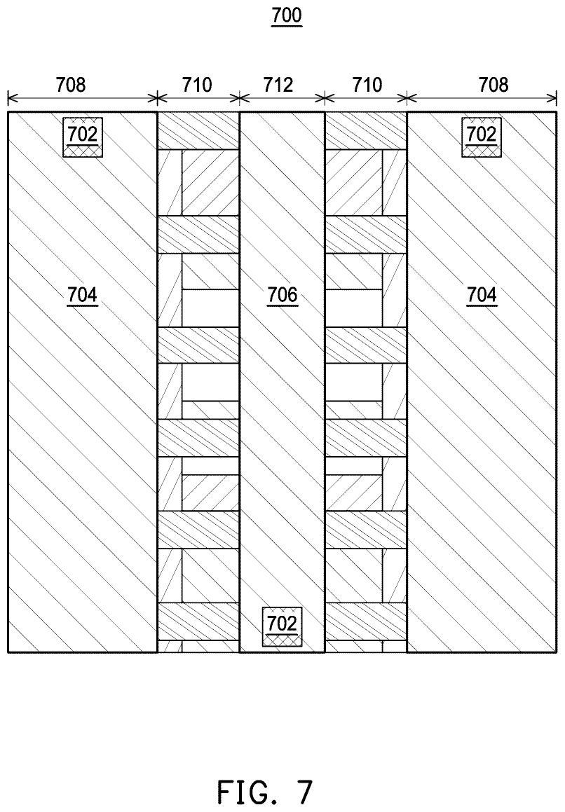

Corresponding to operation 210 of FIG. 2, FIG. 7 illustrates a top view of a fourth metallization layer 700 formed over an active surface of a substrate. More particularly, the fourth metallization layer 700 is depicted as formed over the third metallization layer 600, as where the first, second, third, and fourth metallization layers 400, 500, 600, 700 correspond to M0, M1, M2, and M3 layers. The lines of the fourth metallization layer 700 extend in the lateral direction perpendicular to the first lateral direction of lines of the first and third metallization layers 400, 600, and parallel to the second lateral direction of lines of the second metallization layer 500. The lines electrically couple with the fifth lines 604 and sixth lines 606 of the capacitor by via structures 702, depicted upon the foreground for clarity, but which are disposed between the third metallization layer 600 and the fourth metallization layer 700.

The lines of the fourth metallization layer 700 include seventh lines 704 coupled with the first supply voltage and eighth lines 706 coupled with the second supply voltage. Accordingly, the seventh lines 704 may be referred to as a portion of the first electrode and the eighth lines 706 may be referred to as a portion of the second electrode. The seventh lines 704 can be provided with varying or equal widths and spacings. For example, in some embodiments, the seventh lines 704 are homologated to equal or unequal track widths as described with regard to the first metallization layer 400. For example, the seventh lines 704 can be provided as having a width 708 of about 24 nm or about 48 nm. The eighth lines 706 (depicted as a single line disposed medially between the seventh lines) can be provided with another width 712, such as about 17 nm (e.g., between about 15 nm and about 19 nm) or about 34 nm. The seventh lines 704 can be provided as spaced equally or unequally from the eighth line 706. For example, an equal spacing 710 of about 30 nm may be provided. Like other spacings of the capacitor, the spacing 710 may correspond to a minimum spacing of the process according to DRC rules.

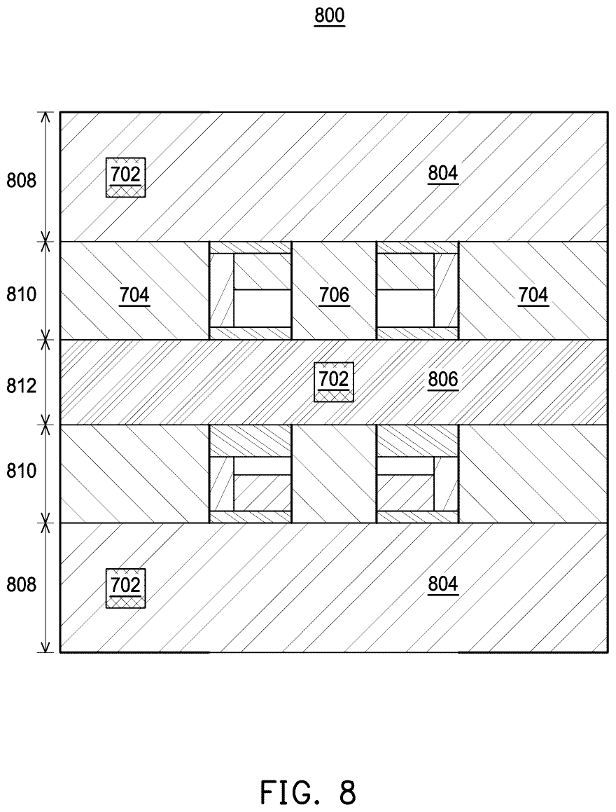

Corresponding to operation 212 of FIG. 2, FIG. 8 illustrates a top view of a fifth metallization layer 800 formed over an active surface of a substrate. More particularly, the fifth metallization layer 800 is depicted as formed over the fourth metallization layer 700, as where the first, second, third, fourth, and fifth metallization layers 400, 500, 600, 700, 800 correspond to M0, M1, M2, M3, and M4 layers, respectively. The lines of the fifth metallization layer 800 extend in the lateral direction parallel to the first lateral direction of lines of the first and third metallization layers 400, 600, and perpendicular to the second lateral direction of lines of the second and fourth metallization layers 500, 700. The lines electrically couple with the seventh lines 704 and eighth lines 706 of the capacitor by via structures 802, depicted upon the foreground for clarity, but which are disposed between the fourth metallization layer 700 and the fifth metallization layer 800.

The lines of the fifth metallization layer 800 include ninth lines 804 coupled with the first supply voltage and tenth lines 806 coupled with the second supply voltage. Accordingly, the ninth lines 804 may be referred to as a portion of the first electrode and the tenth lines 806 may be referred to as a portion of the second electrode. The ninth lines 804 can be provided with varying or equal widths and spacings. For example, in some embodiments, the ninth lines 804 are homologated to equal or unequal track widths as described regarding the first metallization layer 400. For example, the ninth lines 804 can be provided as having a width 808 of about 32 nm. (e.g., between about 15 nm and about 36 nm). The tenth lines 806 (depicted as a single line disposed medially between the ninth lines 804) can be provided with another width 812, such as about 21 nm (e.g., between about 18 nm and about 24 nm). The ninth lines 804 can be provided as spaced equally or unequally from the tenth line 806. For example, an equal spacing 810 of about 22 nm may be provided.

FIG. 9 illustrates an unstacked layer diagram for layers of the capacitor of FIGS. 4-8, in accordance with some embodiments. More particularly, the unstacked layer diagram depicts the first metallization layer 400 and the third metallization layer 600. As depicted, a line of the third metallization layer 600, depicted as a sixth line 606 (but which may include a fifth line 604, in some embodiments) is provided as laterally centered over a line of the first metallization layer 400 (e.g., the second track 408, as depicted). Another line of the first metallization layer 400 is centered over a spacing 610 between lines of the third metallization layer 600 (e.g., a fifth line 604 or a sixth line 606).

FIG. 10 illustrates a capacitance extraction diagram 1000, in accordance with some embodiments. The extraction diagram 1000 depicts various constituent capacitances of the capacitor. The depicted constituent capacitances are intended to be illustrative, and non-limiting. For example, more than one capacitance between lateral lines is provided for each layer, but is depicted as a single instance. Moreover, further capacitances can contribute to a total capacitance, including a capacitance between a poly gate or adjacent MD structure and the M0 layer.

An MD layer 1001 can include at least a first MD structure 1002 and a second MD structure 1004 having a first capacitance 1006 therebetween. The MD layer 1001 can couple with an M0 layer (e.g., the first metallization layer 400) with a contact structure 1003, sometimes referred to as a via diffusion (VD) via structure. The M0 layer includes various lines coupled to one another to form a second capacitance 1008. Likewise, the M1 layer (e.g., the second metallization layer 500) includes various lines coupled to form a third capacitance 1010; the M2 layer (e.g., the third metallization layer 600) includes various lines coupled to form a fourth capacitance 1012; the M3 layer (e.g., the fourth metallization layer 700) includes various lines coupled to form a fifth capacitance 1014; the M4 layer (e.g., the fifth metallization layer 800) includes various lines coupled to form a sixth capacitance 1016.

Interlayer connections can further contribute to the total capacitance. For example, various couplings between the M0 and M1 layers may be referred to, collectively, as a seventh capacitance 1018. Various couplings between the M2 and M3 layers may be referred to, collectively, as an eighth capacitance 1020; various couplings between the M3 and M4 layers may be referred to, collectively, as a ninth capacitance 1022. As indicated above, the illustrated examples should not be construed as limiting. For example, the lack of a depicted capacitance between an M1 and M2 layer should not be construed as a lack of such a capacitance. Indeed, numerous lines, via structures, interconnects, or other aspects of the capacitor can further contribute to the total capacitance.

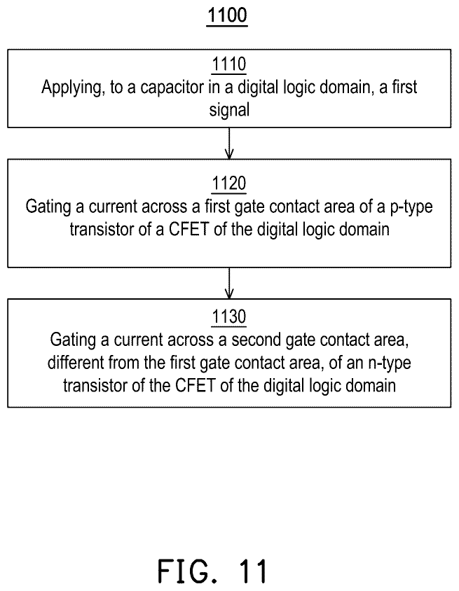

FIG. 11 illustrates an example flow chart of a method 1100 of circuit operation, in accordance with some embodiments. As for the method 200 of FIG. 2, some operations may only be described briefly herein. However, one skilled in the art will understand that the disclosed operations may be performed in conjunction with other disclosed methods disclosed herein, or generally known in the art. Further, the order of the disclosed operations is not intended to be limiting. Certain operations may be performed in a different sequence, and still further operations may be sequenced with appropriate modifications thereto. Moreover, one or more instances of the method 1100 may be performed for various zones of a semiconductor device 100 (e.g., simultaneously).

At operation 1110, the method 1100 includes applying, to a capacitor in a digital logic domain, a first signal. For example, the first signal can include a time-variant signal or nominally direct current (DC) signal exhibiting ripple, as may induce currents in adjoining components. In some embodiments, the signal can include a DC signal without a substantial time-varying component, but can impact other signals in the area according to a capacitive loading of the capacitor, which may also be referred to as inducing a component of such a signal (e.g., a time-delay or skew component).

At operation 1120, the method 1100 includes gating, according to a first gate contact area of an n-type transistor a first current across the n-type transistor. The first gate-contact area may be asymmetric to a second gate contact area of a p-type transistor. However, according to the differing materials and behavior of the p-type and n-type transistors, the asymmetry can normalize an induced current between the respective capacitors. For example, various p-type transistors and n-type transistors of a digital design region may be similarly asymmetrically formed to normalize such currently across various design cells of a semiconductor device (e.g., of a digital logic domain of the semiconductor device).

At operation 1130, the method 1100 includes gating, at a second gate contact area of a p-type transistor greater than the first gate contact area, a second current equal to the first current across the n-type transistor induced by the first signal. The n-type transistor and the p-type transistor may be disposed in the digital logic domain along with the capacitor. For example, the transistors and capacitor can be located in a same design cell or adjacent design cells of the digital logic domain, or otherwise be located in same or abutting design cells (e.g., across a boundary 106). The operations provided herein are not intended to limit the present disclosure. For example, operations or suboperations can be added, substituted, omitted, or otherwise modified.

In one aspect of the present disclosure, a semiconductor device includes a first spatial region for digital design cells. The first spatial region includes a metal-oxide-metal (MOM) capacitor. The mom capacitor includes a first plurality of lines of a first electrode of the MOM capacitor interleaved with a second plurality of lines of a second electrode of the MOM capacitor at a first metallization layer. The semiconductor device includes a second spatial region (e.g., laterally spaced from the first spatial region).

In another aspect of the present disclosure, a capacitor is provided. The capacitor includes a plurality of first lines of a first electrode of the capacitor interleaved with a plurality of second lines of a second electrode of the capacitor at a first metallization layer, wherein one or more of the first lines has a first width and one or more of the first lines has a second width larger than the first width. The capacitor includes a plurality of third lines of the first electrode of the capacitor interleaved with a plurality of fourth lines of the second electrode of the capacitor at a second metallization layer, wherein the third lines and the fourth lines have a third width. The capacitor includes a plurality of fifth lines of the first electrode of the capacitor interleaved with a plurality of sixth lines of the second electrode of the capacitor at a third metallization layer, wherein the fifth lines and the sixth lines have a fourth width. The capacitor includes one or more seventh lines of the first electrode at a fourth metallization layer interleaved with one or more sixth lines of the second electrode. One or more of the seventh lines has a fifth width and one or more of the sixth lines has a sixth width larger than the fifth width. The capacitor includes one or more ninth lines of the first electrode at a fifth metallization layer interleaved with one or more tenth lines of the second electrode. One or more of the ninth lines has a seventh width and one or more of the tenth lines has an eighth width larger than the seventh width. The capacitor includes an interlayer dielectric of a dielectric of the capacitor.

In another aspect of the present disclosure, a method is provided. The method includes applying, to a capacitor in a digital logic domain, a first signal. The method includes gating, according to a first gate contact area of an n-type transistor and a second gate contact area of a p-type transistor greater than the first gate contact area, a first current across the n-type transistor equal to a second current across the p-type transistor induced by the first signal. The capacitor includes a plurality of first lines, having a first width, of a first electrode of the capacitor interleaved with a plurality of second lines, having a second width of a second electrode of the capacitor at a first metallization layer. The capacitor includes a plurality of third lines, having a third width, of the first electrode interleaved with a plurality of fourth lines, having the third width at a second metallization layer. The capacitor includes a plurality of fifth lines, having a fourth width, of the second electrode interleaved with a plurality of sixth lines, having the fourth width, at a third metallization layer.

In another aspect of the present disclosure, a semiconductor device is provided. The semiconductor device includes a first spatial region for digital design cells comprising a complementary field effect transistor (CFET). The first spatial region includes an n-type transistor having a first gate contact area. The first spatial region includes a p-type transistor having a second gate contact area, greater than the first gate contact area. The second spatial region is laterally spaced from the first spatial region. The first spatial region can include a metal-oxide-metal (MOM) capacitor that includes a first plurality of lines of a first electrode of the MOM capacitor interleaved with a second plurality of lines of a second electrode of the MOM capacitor at a first metallization layer.

In another aspect of the present disclosure, a method is provided. The method includes forming a complementary field effect transistor (CFET) including an n-type transistor and a p-type transistor along an active surface of a semiconductor device. The method includes forming a first metallization layer over the CFET, comprising a plurality of first lines of a first electrode of a capacitor interleaved with a plurality of second lines of a second electrode of the capacitor. The method includes forming a second metallization layer over the CFET, comprising a plurality of third lines of the first electrode of the capacitor and a plurality of forth lines of the second electrode of the capacitor, the third lines and fourth lines interleaved with each other and extending perpendicular to the first and second lines. The method includes forming a third metallization layer over the CFET, comprising a plurality of fifth lines of the first electrode of the capacitor and a plurality of sixth lines of the second electrode of the capacitor, the fifth lines and sixth lines interleaved with each other and extending parallel to the first and second lines.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first spatial region for digital design cells comprising a complementary field effect transistor (CFET) including:
an n-type transistor having a first gate contact area; and
a p-type transistor having a second gate contact area, greater than the first gate contact area; and
a second spatial region laterally spaced from the first spatial region,
wherein the first spatial region comprises a metal-oxide-metal (MOM) capacitor that includes a first plurality of lines of a first electrode of the MOM capacitor interleaved with a second plurality of lines of a second electrode of the MOM capacitor at a first metallization layer.

2. The semiconductor device of claim 1, wherein a difference between the first gate contact area and the second gate contact area is configured to normalize a leakage across an n-channel of the n-type transistor and a p-channel of the p-type transistor induced by the MOM capacitor.

3. The semiconductor device of claim 2, wherein the MOM capacitor is in a first digital logic cell laterally abutting a second digital logic cell including the n-type transistor and the p-type transistor.

4. The semiconductor device of claim 1, wherein the second spatial region is an analog domain.

5. The semiconductor device of claim 1, wherein:
one or more of the first lines has a first width and one or more of the first lines has a second width different from the first width; and
one or more of the second lines has a third width and one or more of the second lines has a fourth width different from the third width.

6. The semiconductor device of claim 5, wherein:
the second width is equal to the fourth width; and
a spacing between each of plurality of first lines and the plurality of second lines is equal.

7. The semiconductor device of claim 5, further comprising:
a plurality of third lines of the first electrode, the plurality of third lines having a fifth width at a second metallization layer;
a plurality of fourth lines of the second electrode, the plurality of third lines having the fifth width at the second metallization layer;
a plurality of fifth lines of the first electrode, the plurality of fifth lines having a sixth width at a third metallization layer; and
a plurality of sixth lines of the second electrode, the plurality of sixth lines having the sixth width at the third metallization layer.

8. The semiconductor device of claim 7, wherein the fifth width and the sixth width:
are less than the second width and the fourth width; and
exceed the first width and the third width.

9. The semiconductor device of claim 7, further comprising:
one or more seventh lines of the first electrode at a fourth metallization layer;
one or more eighth lines of the second electrode at the fourth metallization layer;
one or more ninth lines of the first electrode at a fifth metallization layer; and
one or more tenth lines of the second electrode at the fifth metallization layer.

10. The semiconductor device of claim 9, wherein:
the first metallization layer is an M0 layer;
the second metallization layer is an M1 layer;
the third metallization layer is an M2 layer;
the fourth metallization layer is an M3 layer; and
the fifth metallization layer is an M4 layer.

11. A capacitor, comprising:
a plurality of first lines of a first electrode of the capacitor interleaved with a plurality of second lines of a second electrode of the capacitor at a first metallization layer, wherein one or more of the first lines has a first width and one or more of the first lines has a second width larger than the first width;
a plurality of third lines of the first electrode of the capacitor interleaved with a plurality of fourth lines of the second electrode of the capacitor at a second metallization layer, wherein the third lines and the fourth lines have a third width;
a plurality of fifth lines of the first electrode of the capacitor interleaved with a plurality of sixth lines of the second electrode of the capacitor at a third metallization layer, wherein the fifth lines and the sixth lines have a fourth width;
one or more seventh lines of the first electrode at a fourth metallization layer interleaved with one or more eighth lines of the second electrode, wherein one or more of the seventh lines has a fifth width and one or more of the eighth lines has a sixth width larger than the fifth width;
one or more ninth lines of the first electrode at a fifth metallization layer interleaved with one or more tenth lines of the second electrode, wherein one or more of the ninth lines has a seventh width and one or more of the tenth lines has an eighth width larger than the seventh width; and
an interlayer dielectric of a dielectric of the capacitor.

12. The capacitor of claim 11, wherein:
the plurality of first lines comprises one first line having the second width exceeding 16 nanometers, at a first lateral edge of the capacitor opposite from one second line having a ninth width greater than the second width; and
the others of the first and the second lines are disposed laterally between and parallel to the one first line and the one second line.

13. The capacitor of claim 11, wherein:
a sum of a quantity of the third lines and the fourth lines exceeds a sum of a quantity of the fifth lines and the sixth lines; and
the third lines extend perpendicular to the fourth lines.

14. The capacitor of claim 11, wherein, for each of the metallization layers;
outermost lines exhibit a width equal to or greater than other lines of a same metallization layer.

15. The capacitor of claim 11, wherein the fourth width exceeds:
the third width; and
a spacing between the third lines and the fourth lines.

16. The capacitor of claim 11, wherein the others of the first and second lines have a width of about 11 nm and a spacing of about 9.5 nm.

17. The capacitor of claim 11, wherein the third lines and the fourth lines have a width of about 24 nm and the fifth and the sixth lines have a width of about 12 nm and a spacing of about 12.5 nm.

18. A method of fabricating semiconductor devices, comprising:
forming a complementary field effect transistor (CFET) including an n-type transistor and a p-type transistor along an active surface of a semiconductor device;
forming a first metallization layer over the CFET, comprising a plurality of first lines of a first electrode of a capacitor interleaved with a plurality of second lines of a second electrode of the capacitor;
forming a second metallization layer over the CFET, comprising a plurality of third lines of the first electrode of the capacitor and a plurality of forth lines of the second electrode of the capacitor, the third lines and fourth lines interleaved with each other and extending perpendicular to the first and second lines; and
forming a third metallization layer over the CFET, comprising a plurality of fifth lines of the first electrode of the capacitor and a plurality of sixth lines of the second electrode of the capacitor, the fifth lines and sixth lines interleaved with each other and extending parallel to the first and second lines.

19. The method of claim 18, comprising forming the CFET in a digital logic domain to include:
a first gate contact area for the n-type transistor; and
a second gate contact area, greater than the first gate contact area, for the p-type transistor.

20. The method of claim 18, wherein the CFET is disposed in a first digital logic cell abutting a second digital logic cell including the capacitor.
